(19) United States
(12) Patent Application Publication
(10) Pub. No.: US 2026/0123236 A1
(43) Pub. Date: Apr. 30, 2026

(54) ASYMMETRIC AUXILIARY ELECTRODE CONFIGURATION FOR ORGANIC LIGHT EMITTING DIODE DISPLAY

(71) Applicant: Applied Materials, Inc., Santa Clara, CA (US)

(72) Inventors: Chung-Chia CHEN, Hsinchu City (TW); Yu-Hsin LIN, Zhubei City (TW); Ji Young CHOUNG, Hwaseong-si (KR); Sheng-Wen WANG, Tainan City (TW)

(21) Appl. No.: 19/360,740

(22) Filed: Oct. 16, 2025

Related U.S. Application Data
(60) Provisional application No. 63/714,606, filed on Oct. 31, 2024.

(51) Int. Cl. H10K 59/80; H10K 59/122

(52) U.S. Cl. CPC H10K 59/80522; H10K 59/122

(57) ABSTRACT

Embodiments of the present disclosure generally relate to a display. More specifically, embodiments described herein relate to sub-pixel circuits and methods of forming sub-pixel circuits that may be utilized in a display such as an organic light-emitting diode (OLED) display. The device includes a plurality of overhang structures, each overhang structure including a first structure having a first portion opposing a second portion, a second structure disposed over the first structure, wherein an overhang of the second structure extends laterally past an upper surface of the first structure to define the overhang, and an auxiliary electrode is disposed partially under the second portion, and a plurality of sub-pixels defined by the plurality of overhang structures, each sub-pixel including an OLE material, and a cathode disposed over the OLE material, the cathode under the overhang disposed over the second portion of the first structure contacts the auxiliary electrode.

### CROSS-REFERENCE TO RELATED APPLICATIONS

This application claims the benefit of U.S. Provisional Application No. 63/714,606, filed on October 31, 2024, which is incorporated by reference herein in its entirety.

### BACKGROUND

### Field

Embodiments of the present disclosure generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today’s electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance.

Accordingly, what is needed in the art are OLED pixels and method of forming OLED pixels to increase pixel-per-inch and provide improved OLED performance.

### SUMMARY

In a first embodiment, a device is disclosed. The device includes a plurality of overhang structures, each overhang structure of the plurality of overhang structures including a first structure having a first portion opposing a second portion, a second structure disposed over the first structure, wherein an overhang of the second structure extends laterally past an upper surface of the first structure to define the overhang, and an auxiliary electrode is disposed partially under the second portion, and a plurality of sub-pixels defined by the plurality of overhang structures, each sub-pixel including an organic light emitting (OLE) material, and a cathode disposed over the OLE material, the cathode under the overhang disposed over the second portion of the first structure contacts the auxiliary electrode.

In another embodiment, a device is disclosed. The device includes a first sub-pixel defined by a first overhang structure and a second overhang structure, a second sub-pixel, the second sub-pixel is defined by the second overhang structure and a third overhang structure, each overhang structure of a plurality of overhang structures include a first structure and a second structure disposed over the first structure, wherein an overhang of the second structure extends laterally past an upper surface of the first structure to define the overhang and the second overhang structure has an auxiliary electrode disposed under the first structure and wherein each of the first sub-pixel and the second sub-pixel include an organic light emitting (OLE) material and a cathode disposed over the OLE material, the cathode contacts the auxiliary electrode of the second overhang structure.

In another embodiment, a device is disclosed. The device includes a plurality of sub-pixels, each sub-pixel of the plurality of sub-pixels defined by adjacent pixel-defining layer (PDL) structures with a plurality of overhang structures disposed over a plurality of PDL structures, each sub-pixel of the plurality of sub-pixels having an anode, an auxiliary electrode, an organic light-emitting (OLE) material disposed on the anode, and a cathode disposed on the OLE material, wherein the device is made by a process comprising the steps of: depositing the OLE material using evaporation deposition over a substrate, the OLE material disposed over and in contact with the anode, depositing the cathode using evaporation deposition, the cathode disposed over the OLE material and extending under the overhang structures adjacent to each sub-pixel of the plurality of sub-pixels, and depositing an encapsulation layer disposed over the cathode, the encapsulation layer extending under at least a portion of the overhang structures and along a sidewall of the overhang structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of the scope of the disclosure, and may admit to other equally effective embodiments.

FIG. 1 is a schematic, cross-sectional view of an asymmetrical sub-pixel circuit, according to some embodiments.

FIG. 2A and 2B are schematic, cross-sectional views of an overhang structure, according to certain embodiments.

FIG. 3A and 3B are schematic, top-sectional views of a sub-pixel circuit, according to certain embodiments.

FIG. 4 is a schematic, cross-sectional view of an overhang structure of a sub-pixel circuit, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In one embodiment, which can be combined with other embodiments described herein, the display is a bottom emission (BE) or a top emission (TE) OLED display. In another embodiment, which can be combined with other embodiments described herein, the display is a passive-matrix (PM) or an active matrix (AM) OLED display.

Each of the embodiments described herein of the sub-pixel circuit include a plurality of sub-pixels with each of the sub-pixels defined by adjacent overhang structures that are permanent to the sub-pixel circuit. While the Figures depict one sub-pixel with the sub-pixel defined by adjacent overhang structures, the sub-pixel circuit of the embodiments described herein include a plurality of sub-pixels, such as two or more sub-pixels. Each sub-pixel has the organic light emitting (OLE) material configured to emit a white, red, green, blue or other color light when energized. For example, the OLE material of a first sub-pixel emits a red light when energized, the OLE material of a second sub-pixel emits a green light when energized, and the OLE material of a third sub-pixel emits a blue light when energized.

The overhangs are permanent to the sub-pixel circuit and include at least a second structure disposed over a first structure. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLE materials (including a hole injection layer (HIL), a hole transport layer (HTL), an emissive layer (EML), and an electron transport layer (ETL)) and a cathode. In some instances, an encapsulation layer is deposited via evaporation deposition. In embodiments including one or more capping layers, the capping layers are disposed between the cathode and the encapsulation layer. The encapsulation layer of a respective sub-pixel is disposed over the cathode. The embodiments disclosed herein further include an auxiliary electrode disposed under at least a portion of the overhang structures. For example, the auxiliary electrode is disposed over the pixel-defining layer (PDL) and under the first structure of the overhang. In another example, the auxiliary electrode is disposed under a portion (e.g., half) of the first structure of the overhang.

In conventional OLED devices lateral leakage occurs if a conductive organic layer (e.g., HIL or HTL) contacts the first structure of the overhang. Vertical leakage occurs if a distance between the cathode and the conductive organic layer(s) is thin. An auxiliary electrode prevents both lateral leakage and vertical leakage by providing an optimized cathode contact configuration by adjusting the deposition angles of cathode and OLE material in order to control where the cathode is deposited in the sub-pixel. The auxiliary electrode creates an asymmetric sub-pixel circuit to control the deposition angles. The auxiliary electrode further provides improved yield, improved power consumption performance, improved color purity, and an additional margin for evaporation source design.

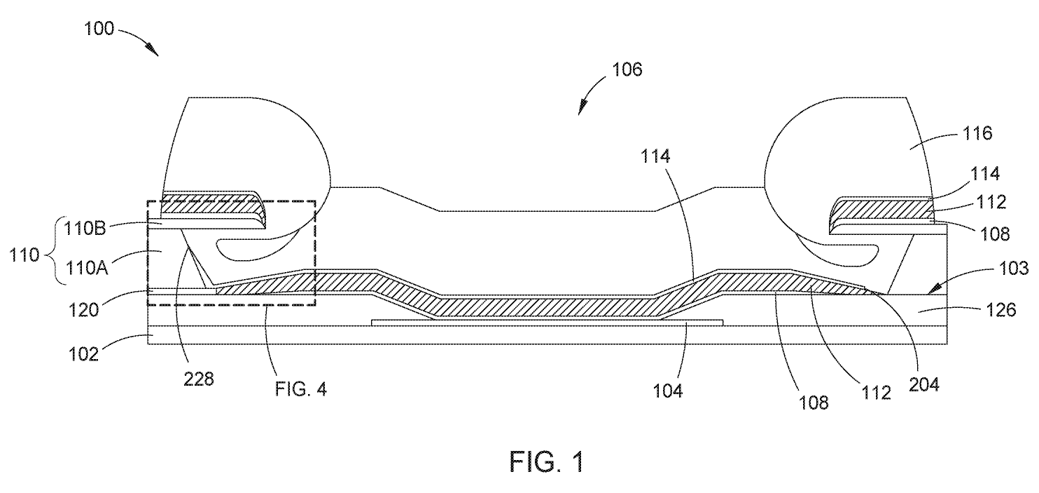

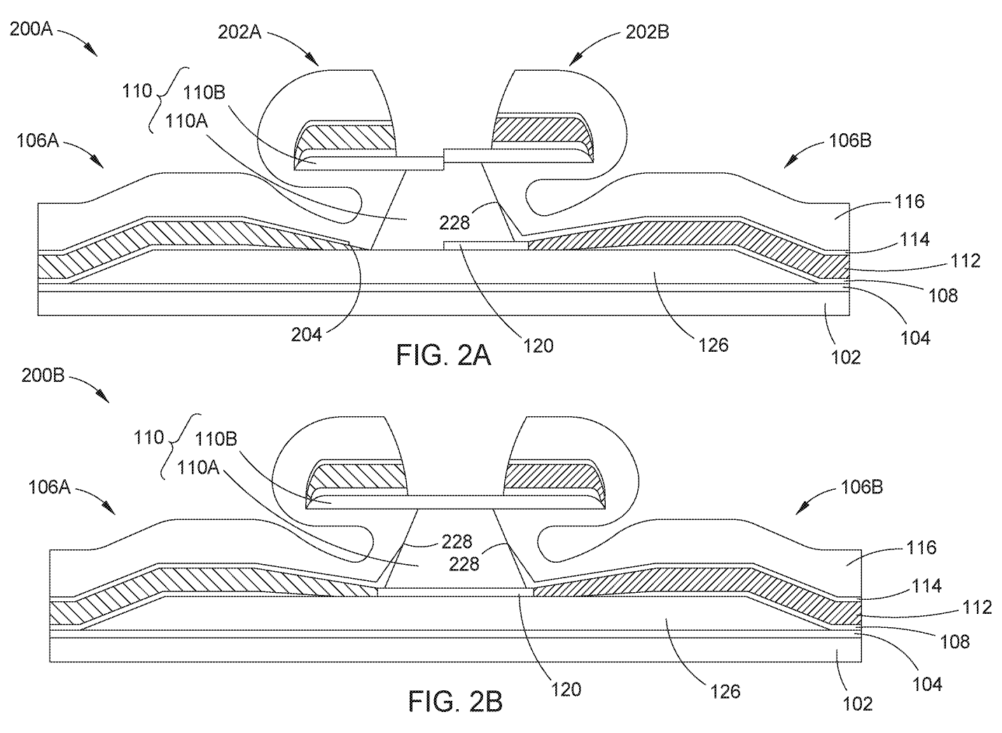

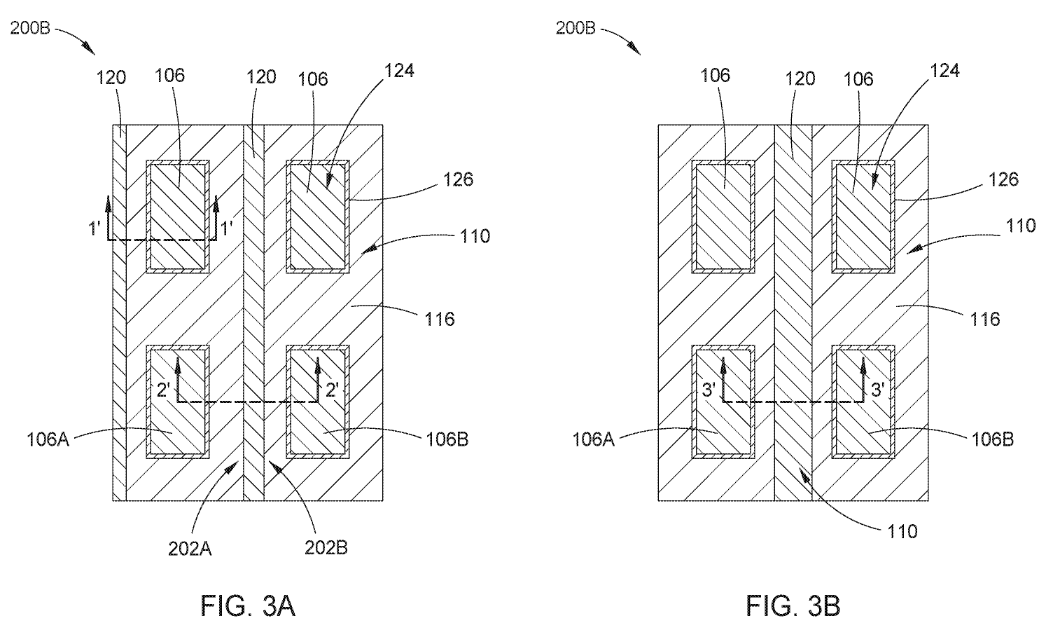

FIG. 1 is a schematic, cross-sectional view of an asymmetrical sub-pixel circuit 100. The cross-sectional views of FIG. 1 are taken along section line 1’-1’ of FIG. 3A. FIG. 2A and 2B are schematic, cross-sectional views of an overhang structure 110. FIG. 2A shows a partial layer auxiliary electrode configuration 200A. FIG. 2B shows a full layer auxiliary electrode configuration 200B.

The asymmetrical sub-pixel circuit 100 includes a substrate 102. Metal layers 104 may be patterned on the substrate 102 and are defined by adjacent pixel-defining layer (PDL) structures 126 disposed on the substrate 102. In one embodiment, which can be combined with other embodiments described herein, the metal layers 104 are pre-patterned on the substrate 102. For example, the substrate 102 is a pre-patterned indium tin oxide (ITO) glass substrate. The metal layers 104 are configured to operate as anodes of respective sub-pixels. In one or more embodiments, the metal layers 104 are metal-containing layers. The metal layers 104 include, but are not limited to, chromium, titanium, gold, silver, copper, aluminum, ITO, a combination thereof, or other suitably conductive materials. In one or more embodiments the metal layers 104 are disposed within the sub-pixel 106, as shown in FIG. 1. In one or more embodiments, the metal layers 104 are disposed over the substrate 102 such that the metal layers 104 are disposed within the sub-pixel 106 and partially under the PDL structures 126, as shown in FIG. 2A and FIG. 2B.

The PDL structures 126 are disposed on the substrate 102. The PDL structures 126 include one of an organic material, an organic material with an inorganic coating disposed thereover, or an inorganic material. The organic material of the PDL structures 126 includes, but is not limited to, polyimides. The inorganic material of the PDL structures 126 includes, but is not limited to, silicon oxide (SiO₂), silicon nitride (Si₃N₄), silicon oxynitride (Si₂N₂O), magnesium fluoride (MgF₂), or combinations thereof. Adjacent PDL structures 126 define a respective sub-pixel and expose the anode (i.e., metal layer 104) of the respective sub-pixel of the asymmetrical sub-pixel circuit 100.

The sub-pixel circuit 100 has a plurality of sub-pixels including at least a sub-pixel 106. While the Figures depict the sub-pixel 106, the asymmetrical sub-pixel circuit 100 of the embodiments described herein may include two or more sub-pixels, such as a third and a fourth sub-pixel. Each sub-pixel 106 has an OLE material 112 configured to emit a white, red, green, blue or other color light when energized. For example, the OLE material 112 of the sub-pixel 106 emits a red light when energized, the OLE material of a second sub-pixel emits a green light when energized, the OLE material of a third sub-pixel emits a blue light when energized, and the OLE material of a fourth sub-pixel emits another color light when energized.

Overhang structures 110 are disposed over an upper surface 103 of each of the PDL structures 126. The overhang structures 110 are permanent to the sub-pixel circuit. The overhang structures 110 further define each sub-pixel 106 of the asymmetrical sub-pixel circuit 100. The overhang structures 110 include at least a second structure 110B disposed on a first structure 110A.

The second structure 110B includes one of an inorganic material, or a metal-containing material. The first structure 110A includes one of an inorganic material, or a metal-containing material. The inorganic material may be non-conductive. The non-conductive inorganic material includes, but is not limited to, an inorganic silicon-containing material. For example, the silicon-containing material includes oxides or nitrides of silicon, or combinations thereof. The metal-containing material includes, but is not limited to, copper, titanium, aluminum, molybdenum, silver, indium tin oxide (ITO), indium zinc oxide (IZO), or combinations thereof.

In one or more embodiments, an auxiliary electrode 120 is disposed under the first structure 110A of some of the overhang structures 110. The auxiliary electrode 120 is disposed between the PDL structure126 and the first structure 110A. In one or more embodiments, the auxiliary electrode 120 contacts both the upper surface 103 of the PDL and bottom surface 101 of the first structure 110A. The auxiliary electrode 120 includes a conductive material. For example, the auxiliary electrode 120 includes transparent conductive oxide material (e.g., ITO, IZO, or aluminum-doped zinc oxide (AZO), aluminum, titanium, molybdenum, copper, silver, or combinations thereof.

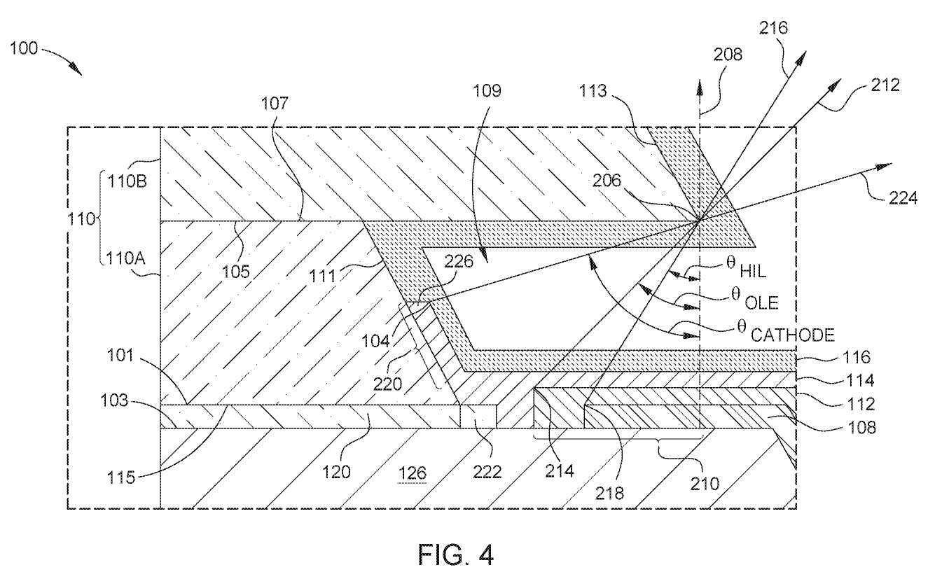

At least a bottom surface 107 of the second structure 110B is wider than a top surface 105 of the first structure 110A to form an overhang 109. The bottom surface 107 larger than the top surface 105 forming the overhang 109 allows for the second structure 110B to shadow the first structure 110A. The shadowing of the overhang 109 provides for evaporation deposition each of the OLE material 112 and a cathode 114. As further discussed in the corresponding description of FIG. 4, the shadowing effect of the overhang structures 110 define a OLE material angle θ_{OLE} (shown in FIG. 4) of the OLE material 112 and a cathode angle θ_{cathode} (shown in FIG. 4) of the cathode 114. The OLE material angle θ_{OLE} of the OLE material 112 and the cathode angle θ_{cathode} of the cathode 114 may result from evaporation deposition of the OLE material 112 and the cathode 114. In some embodiments, the OLE material 112 does not contact and the cathode 114 contacts the first structure 110A of the overhang structures 110.

The OLE material 112 may include one or more of a HIL, a HTL, an EML, and an ETL. The OLE material 112 is disposed on the metal layer 104. In some embodiments, which can be combined with other embodiments described herein, the OLE material 112 is disposed on the metal layer 104 and over a portion of the PDL structures 126. The cathode 114 is disposed over the OLE material 112 and the PDL structures 126 in each sub-pixel 106. The cathode 114 may be disposed over a portion of a sidewall 111 of the first structure 110A. The cathode 114 includes a conductive material, such as a metal. For example, the cathode 114 includes, but is not limited to, silver, magnesium, chromium, titanium, aluminum, ITO, or a combination thereof. In some embodiments, which can be combined with other embodiments described herein, the OLE material 112 and the cathode 114 are disposed over a sidewall 113 of the second structure 110B of the overhang structures 110. In other embodiments, which can be combined with other embodiments described herein, the OLE material 112 and the cathode 114 are disposed over a top surface 115 of the second structure110B of the overhang structures 110.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLE material 112) with the encapsulation layer 116 extending under at least a portion of each of the overhang structures 110. The encapsulation layer 116 is disposed over the cathode 114 and over at least the sidewall 111 of the first structure 110A. In some embodiments, which can be combined with other embodiments described herein, the encapsulation layer 116 is disposed over the sidewall 113 of the second structure 110B. In some embodiments, which can be combined with other embodiments described herein, the encapsulation layer 116 is disposed over the top surface 115 of the second structure 110B of the overhang structures 110. The encapsulation layer 116 includes the non-conductive inorganic material, such as the silicon-containing material. The silicon-containing material may include Si₃N₄ containing materials.

In one or more embodiments, a global passivation layer is disposed over the overhang structures 110 and the encapsulation layers 116. An inkjet layer may be disposed between the global passivation layer and the overhang structures 110 and the encapsulation layers 116.

As shown in FIG. 2A, the auxiliary electrode 120 is disposed over a portion of the PDL structure 126 and under a portion of the first structure 110A as a partial layer auxiliary electrode configuration 200A. The cross-sectional view of FIG. 2A is taken along line 2’-2’ shown in FIG. 3A. FIG. 2A shows a first sub-pixel 106A and a second sub-pixel 106B. In one or more embodiments, the first sub-pixel 106A may include a different OLE material 112 than the second sub-pixel 106B such that the first sub-pixel 106A includes a different color than the second sub-pixel 106B. In one or more embodiments, the overhang structure 110 includes a first portion 202A and a second portion 202B. The second portion 202B of the overhang structure 110 includes the auxiliary electrode 120. For example, the auxiliary electrode 120 contacts the bottom surface 101 of the second portion 202B of the first structure 110A. The first portion 202A of the overhang structure 110 has a different height from the substrate 102 than the second portion 202B of the overhang structure 110 from the substrate 102 . For example, as shown in FIG. 2A, the second portion 202B has a greater height from the substrate 102 than the first portion 202A. The auxiliary electrode 120 includes a thickness of about 10 nm to about 300 nm. The thickness of the auxiliary electrode 120 under the first structure 110A results in the height difference between the second portion 202B and the first portion 202A. The varying heights between the second portion 202B and the first portion 202A allows for design freedom of the deposition angle during processing. For example, an evaporation source is rotated or tilted such that the cathode 114 includes a larger deposition angle over the second portion 202B and a smaller deposition angle over the first portion 202A. The asymmetric design of the sub-pixel allows for maximization of contact for the cathode 114 over the second portion 202B (e.g., a portion with the auxiliary electrode 120). Further, the asymmetric design allows for more OLE material 112 to be deposited over the second portion 202B when compared to the first portion 202A, which allows for current leakage to be mitigated.

For example, as shown in FIG. 2A, the cathode 114 contacts a sidewall 111 of the first structure 110A of the second portion 202B. For example, as shown in FIG. 2A, the cathode 114 contacts the OLE material 112 (e.g., the cathode 114 does not contact the first structure 110A of the first portion 202A). In one or more embodiments, the cathode 114 contacts the auxiliary electrode 120. Further, the HIL 108 is deposited further away from the first structure 110A of the second portion 202B when compared to the HIL 108 deposited in the first portion 202A. In one or more embodiments, as shown in FIG. 3A, the partial layer auxiliary electrode configuration 200A includes an auxiliary electrode under a portion (e.g., the second portion 202B) of every overhang structure 110 within the asymmetrical sub-pixel circuit 100. In other words, each sub-pixel 106 is defined by a first portion 202A and a second portion 202B, as shown in FIG. 1.

In one or more embodiments, the cathode 114 has an end point under each overhang 109 of the overhang structure 110. For example, a short end point 204 of the cathode 114 in the first portion 202A is shown in FIG. 2A (e.g., the short end point 204 is the end point when there is no auxiliary electrode 120). In the first portion 202A, the OLE material 112 under the overhang structure 110 extends past the cathode 114, as shown in FIG. 2A. Further, for example, a long end point 228 of the cathode 114 in the second portion 202B is shown in FIG. 2A (e.g., the long end point 228 is the end point when there is an auxiliary electrode 120). The short end point 204 and the long end point 228 are positioned in different locations within each sub-pixel (e.g., the first sub-pixel 106A and the second sub-pixel 106B).

The asymmetrical sub-pixel circuit 100 includes the plurality of overhang structures 110 Each overhang structure of the plurality of overhang structures 110 includes the first structure 110A having the first portion 202A opposing the second portion 202B. The second structure 110B is disposed on the first structure 110A. An overhang 109 of the second structure 110B extends laterally past an top surface 105 of the first structure 110A to define an overhang 109 (e.g., an overhang extension). The auxiliary electrode 120 is disposed partially under the second portion 202B. The plurality of sub-pixels 106 are defined by the plurality of overhang structures 110. Each sub-pixel 106 includes the organic light emitting (OLE) material 112 and the cathode 114 disposed over the OLE material 112. The cathode 114 under the overhang extension disposed over the second portion 202B of the first structure 110A contacts the auxiliary electrode 120 and the second portion 202B as disclosed and shown in FIG. 2A.

As shown in FIG. 2B, the auxiliary electrode 120 is disposed over the PDL structure 126 and under the first structure 110A as the full layer auxiliary electrode configuration 200B. The cross-sectional view of FIG. 2B is taken along line 3’-3’ shown in FIG. 3B. FIG. 2B shows a first sub-pixel 106A and a second sub-pixel 106B. In one or more embodiments, the first sub-pixel 106A may include a different OLE material 112 than the second sub-pixel 106B such that the first sub-pixel 106A includes a different color than the second sub-pixel 106B. The auxiliary electrode 120 contacts the bottom surface 101 of the first structure 110A. For example, as shown in FIG. 2B, the auxiliary electrode 120 contacts the entirety of the bottom surface 101 of the first structure 110A and at least a portion of the PDL structure 126. In the asymmetrical sub-pixel circuit 100 with the full layer auxiliary electrode configuration 200B, one overhang structure 110 will include the auxiliary electrode 120 and the overhang structure 110 that is adjacent will not include the auxiliary electrode 120, as shown in FIG. 1. The two adjacent overhang structures (e.g., the overhang structures 110 shown in FIG. 1) have different heights. In one or more embodiments, the varying height may be defined as the distance from the substrate 102 to the second structure 110B. The height difference is based on the size of the auxiliary electrode 120. In one or more embodiments, the auxiliary electrode includes a height of about 10 nm to about 300 nm. The varying heights between two adjacent overhangs allows for design freedom of the deposition angle during processing.

As shown in FIG. 2B, the cathode 114 contacts each sidewall 111 of the first structure 110A of the overhang structure 110. In one or more embodiments, the cathode 114 contacts the auxiliary electrode 120. Further, the HIL 108 is deposited further away from the first structure 110A of the full layer auxiliary electrode configuration 200B when compared to an embodiment without an auxiliary electrode 120 due to the adjustment of the deposition angle. The distance of the HIL 108 from the first structure 110A reduces lateral leakage. In one or more embodiments, as shown in FIG. 3B, the full layer auxiliary electrode configuration 200B includes an auxiliary electrode under every other overhang within the asymmetrical sub-pixel circuit 100. In other words, each sub-pixel 106 is defined by an overhang structure 110 disposed over an auxiliary electrode 120 and one overhang structure disposed over a PDL structure 126, as shown in FIG. 1.

In one or more embodiments, the cathode 114 has an end point under each overhang 109 of the overhang structure 110. For example, as shown in FIG. 2B, where the auxiliary electrode 120 is full layer auxiliary electrode configuration 200B, each end point is a long end point 228 on each side of the overhang structure 110. For example, as shown in FIG. 2B, the cathode 114 includes the same end point (e.g., the long end point 206) on both sides of the first structure 110A. As shown in FIG. 1, the overhang structure 110 on an opposite side of a sub-pixel 106 of the overhang structure with the full layer auxiliary electrode configuration 200B includes a short end point 204. In one or more embodiments, when the cathode 114 includes a short end point 204, the OLE material 112 extends past the cathode 114. In one or more embodiments, when the cathode 114 includes a long end point 228, the cathode 114 extends past the OLE material 112.

The asymmetrical sub-pixel circuit 100 includes a first sub-pixel 106A defined by a first overhang structure (e.g., the overhang structure 110) and a second overhang structure, a second sub-pixel 106B, the second sub-pixel 106B is defined by the second overhang structure and a third overhang structure, each overhang structure of a plurality of overhang structures including a first structure 110A and a second structure 110B disposed on the first structure 110A, an overhang 109 of the second structure 110B extends laterally past an top surface 105 of the first structure 110A to define an overhang 109 and the second overhang structure has an auxiliary electrode 120 disposed under the first overhang structure, and wherein each of the first sub-pixel 106A and the second sub-pixel106B include an organic light emitting (OLE) material 112 and a cathode 114 disposed over the OLE material 112, the cathode 114 contacts the auxiliary electrode 120 of the second overhang structure is disclosed and shown in FIG. 2B.

FIGS. 3A and 3B are schematic, top-sectional views of an asymmetrical sub-pixel circuit 100. FIG. 3A is a top-sectional view of an asymmetrical sub-pixel circuit 100 with the partial layer auxiliary electrode configuration 200A. FIG. 3B is a top-sectional view of an asymmetrical sub-pixel circuit 100 with the full layer auxiliary electrode configuration 200B. As shown in FIG. 3A and 3B, the asymmetrical sub-pixel circuit 100 includes a plurality of pixel openings 124. Each pixel opening 124 is surrounded by overhang structures 110 that define each of the sub-pixels 106. Further, in one or more embodiments, the PDL structures 126 surrounds each pixel opening 124. As shown in FIG. 3A, the auxiliary electrode 120 is disposed under the second portion 202B of the overhang structure 110 (e.g., the auxiliary electrode 120 is not disposed under the first portion 202A) to form the partial layer auxiliary electrode configuration 200A. As shown in FIG. 3B, the auxiliary electrode 120 is disposed under the overhang structure 110 to form the full layer auxiliary electrode configuration 200B.

FIG. 4 is a schematic, cross-sectional view of an overhang structure 110 of an asymmetrical sub-pixel circuit 100. While FIG. 4 depicts configurations of the overhang structures 110, the description herein is applicable to a first configuration of the overhang structures 110 including the second structure 110B of a non-conductive inorganic material and the first structure 110A of a conductive inorganic material, and a second configuration of the overhang structures 110 including the second structure 110B of a conductive inorganic material and the first structure 110A of a conductive inorganic material. For example, the OLE material 112 does not contact and the cathode 114 contacts the first structure 110A of the overhang structures 110. In another example, the OLE material 112 does not contact the first structure 110A and the auxiliary electrode 120, and the cathode 114 contacts at least the auxiliary electrode 120.

The second structure 110B includes an underside edge 206 and an overhang vector 208. The underside edge 206 extends past the sidewall 111 of the first structure 110A. The overhang vector 208 is defined by the underside edge 206 and the PDL structure 126. The OLE material 112 is disposed over the anode and over a shadow portion 210 of the PDL structure 126. The OLE material 112 forms an OLE material angle θ_{OLE} between an OLED vector 212 and the overhang vector 208. The OLED vector 212 is defined by an OLED edge 214 extending under the second structure 110B and the underside edge 206 of the second structure 110B. In one embodiment, which can be combined with other embodiments described herein, a HIL 108 of the OLE material 112 included. In the embodiment including the HIL 108, the OLE material 112 includes the HTL, the EML, and the ETL. The HIL 108 forms an HIL angle θ_{HIL} between a HIL vector 216 and the overhang vector 208. The HIL vector 216 is defined by an HIL edge 218 extending under the second structure 110B and the underside edge 206 of the second structure 110B.

The cathode 114 is disposed over the OLE material 112 and over the shadow portion 210 of the PDL structure 126. In some embodiments, which can be combined with other embodiments described herein, the cathode 114 is disposed on a portion 220 of the sidewall 111 of the first structure 110A. In other embodiments, which can be combined with other embodiments described herein, the cathode 114 contacts a portion 222 of the auxiliary electrode 120 on the shadow portion 210 of the PDL structures 126. In the embodiments with the cathode 114 contacting the portion 222 of the auxiliary electrode 120, the cathode 114 may also contact the portion 220 of the sidewall 111 of the first structure 110A. The cathode 114 forms a cathode angle θ_{cathode} between a cathode vector 224 and the overhang vector 208. The cathode vector 224 is defined by a cathode edge 226 at least extending under the second structure 110B and the underside edge 206 of the second structure 110B. The encapsulation layer 116 is disposed over the cathode 114 (and OLE material 112) with the encapsulation layer 116 extending at least under the second structure 110B of the overhang structure 110 and along the sidewall 111 of the first structure 110A.

During evaporation deposition of the OLE material 112, the underside edge 206 of the second structure 110B defines the position of the OLED edge 214. For example, the OLE material 112 is evaporated at an OLE material maximum angle that corresponds to the OLED vector 212 and the underside edge 206 ensures that the OLE material 112 is not deposited past the OLED edge 214. In embodiments with the HIL 108, the underside edge 206 of the second structure 110B defines the position of the HIL edge 218. For example, the HIL 108 is evaporated at an HIL maximum angle that corresponds to the HIL vector 216 and the underside edge 206 ensures that HIL 108 is not deposited past the HIL edge 218. During evaporation deposition of the cathode 114, the underside edge 206 of the second structure 110B defines the position of the cathode edge 226. For example, the cathode 114 is evaporated at a cathode maximum angle that corresponds to the cathode vector 224 and the underside edge 206 ensures that the cathode 114 is not deposited past the cathode edge 226. The OLE material angle θ_{OLE} is less than the cathode angle θ_{cathode}. The HIL angle θ_{HIL} is less than the OLE material angle θ_{OLE.}

In one or more embodiments, the auxiliary electrode is disposed under at least a portion of the overhang structure 110, the deposition angle of the cathode 114 is altered so that the cathode contacts the first structure 110A of the overhang structure 110. For example, as shown in FIG. 1, FIG. 2A, and FIG. 2B, when the auxiliary electrode 120 is disposed under at least a portion of the overhang structure 110, the cathode 114 contacts the first structure 110A of the overhang structure 110. Further, in this example, the HIL 108 is deposited further from the overhang structure 110. In an embodiment without the auxiliary electrode 120, as shown in FIG. 1 and FIG. 2A, when the overhang structure 110 is disposed over the PDL structure 126, the cathode 114 does not contact the first structure 110A of the overhang structure 110. Further, in this example, the HIL 108 is deposited closer to the overhang structure 110. The adjusted deposition angels resulting in varying layer deposition results in a reduced lateral leakage and vertical leakage. In one or more embodiments, the cathode 114 contacts the auxiliary electrode 120 (e.g., the cathode 114 does not contact the overhang structure 110).

A method of forming the asymmetrical sub-pixel circuit 100 is provided. In an exemplary method, a substrate 102 is provided. At a first operation, metal layers 104 (e.g., anodes) and PDL structures 126 are formed on the substrate 102. In one or more embodiments, the metal layers 104 and PDL structures 126 are formed on the substrate via a patterning method using a resist. At a second operation, the auxiliary electrode 120 is deposited over at least a portion of at least one PDL structure 126. In one or more embodiments, an auxiliary electrode layer is deposited over the substrate 102, a photoresist is patterned over the auxiliary electrode layer, and at least a portion of the auxiliary electrode layer is etched away to form the auxiliary electrode 120 disposed over at least a portion of at least one PDL structure 126. At a third operation, overhang structures 110 are formed over the PDL structures. In one or more embodiments, the overhang structures 110 are formed by depositing a lower portion layer and an upper portion layer and then etching each layer to form the overhang structures. At a fourth operation, the OLE material 112, the cathode 114, and the encapsulation layer 116 are deposited over at least the first sub-pixel 106A. As further discussed in the corresponding description of FIG. 2, the shadowing effect of the overhang structures 110 define the OLE material angle θ_{OLE} (shown in FIG. 2) of the OLE material 112 and the cathode angle θ_{cathode} (shown in FIG. 2) of the cathode 114. The OLE material angle θ_{OLE} of the OLE material 112 and the cathode angle θ_{cathode} of the cathode 114 result from evaporation deposition of the OLE material 112 and the cathode 114. In one or more embodiments, additional capping layers are deposited over the first sub-pixel 106A. In additional operations, the process is repeated to form additional sub-pixels.

A device including a plurality of sub-pixels, each sub-pixel of the plurality of sub-pixels defined by adjacent pixel-defining layer (PDL) structures with a plurality of overhang structures disposed over a plurality of PDL structures, each sub-pixel of the plurality of sub-pixels having an anode, an auxiliary electrode, an organic light-emitting (OLE) material disposed on the anode, and a cathode disposed on the OLE material, wherein the device is made by a process comprising the steps of: depositing the OLE material using evaporation deposition over a substrate, the OLE material disposed over and in contact with the anode; depositing the cathode using evaporation deposition, the cathode disposed over the OLE material and extending under the overhang structures adjacent to each sub-pixel of the plurality of sub-pixels; and depositing an encapsulation layer disposed over the cathode, the encapsulation layer extending under at least a portion of the overhang structures and along a sidewall of the overhang structures.

Embodiments of the present disclosure generally relate to a display. More specifically, embodiments described herein relate to sub-pixel circuits and methods of forming sub-pixel circuits that may be utilized in a display such as an OLED display. In conventional OLED devices lateral leakage occurs if a conductive organic layer (e.g., HIL or HTL) contacts the first structure of the overhang. Vertical leakage occurs if the distance between the cathode and the conductive organic layer(s) is thin. The auxiliary electrode prevents both lateral leakage and vertical leakage by providing an optimized cathode contact configuration. In conventional methods, the cathode must contact the conductive overhang sidewall. The auxiliary electrode provides a contact surface to the cathode without the need for the cathode to contact the conductive overhang sidewall. Further, the auxiliary electrode eliminates the risk of conductive overhang sidewall oxidation. The advantage to the asymmetric design is that the asymmetric design allows for flexibility of deposition angle during manufacturing of the sub-pixels. For example, during thermal evaporation by scanning, the deposition angle can be optimized to the overhang structure with the auxiliary electrode. The optimization of the deposition angle for the cathode and/or OLE material reduces the risk of current leakage during operation of the OLED device. The auxiliary electrode is operable to direct the deposition of the cathode such that the cathode contacts the sidewall of the first structure of the overhang structures to reduce or prevent vertical leakage. Further, the auxiliary electrode is operable to direct the deposition of at least the HIL to reduce lateral leakage. The auxiliary electrode creates an asymmetric sub-pixel circuit to control the deposition angles. The auxiliary electrode further provides improved yield, improved power consumption performance, improved color purity, and additional margin for evaporation source design.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a plurality of overhang structures, each overhang structure of the plurality of overhang structures comprising:
a first structure having a first portion opposing a second portion;
a second structure disposed over the first structure, wherein:
an overhang of the second structure extends laterally past an upper surface of the first structure to define the overhang; and
an auxiliary electrode is disposed partially under the second portion; and
a plurality of sub-pixels defined by the plurality of overhang structures, each sub-pixel comprising:
an organic light emitting (OLE) material; and
a cathode disposed over the OLE material, the cathode under the overhang disposed over the second portion of the first structure contacts the auxiliary electrode.

2. The device of claim 1, further comprising adjacent pixel-defining layer (PDL) structures which define a sub-pixel, wherein each overhang of the plurality of overhang structures is disposed over each PDL structure of the adjacent PDL structures and the auxiliary electrode is disposed between the PDL structure and the first structure.

3. The device of claim 1, wherein the cathode disposed under the overhang contacts the auxiliary electrode and the first structure of the second portion.

4. The device of claim 1, wherein the second structure of the second portion is higher than the second structure of the first portion.

5. The device of claim 4, wherein a height difference between the first portion and the second portion is about 10 nm to about 300 nm.

6. The device of claim 1, wherein the first portion and the second portion comprise half of each overhang structure of the plurality of overhang structures.

7. The device of claim 1, wherein the auxiliary electrode comprises a conductive material.

8. The device of claim 7, wherein the conductive material comprises transparent conductive oxide material, aluminum, titanium, molybdenum, copper, silver, or combinations thereof.

9. A device, comprising:
a first sub-pixel defined by a first overhang structure and a second overhang structure;
a second sub-pixel, the second sub-pixel is defined by the second overhang structure and a third overhang structure, each overhang structure of a plurality of overhang structures comprises:
a first structure; and
a second structure disposed over the first structure, wherein:
an overhang of the second structure extends laterally past an upper surface of the first structure to define the overhang; and
the second overhang structure has an auxiliary electrode disposed under the first structure; and
wherein each of the first sub-pixel and the second sub-pixel include:
an organic light emitting (OLE) material; and
a cathode disposed over the OLE material, the cathode contacts the auxiliary electrode of the second overhang structure.

10. The device of claim 9, further comprising adjacent pixel-defining layer (PDL) structures which define a sub-pixel, wherein each overhang of the plurality of overhang structures is disposed over each PDL structure of the adjacent PDL structures and the auxiliary electrode is disposed between the PDL structure and the first structure.

11. The device of claim 9, wherein the cathode contacts a sidewall of the first structure of the second overhang structure and the cathode contacts the auxiliary electrode.

12. The device of claim 9, wherein the cathode under the overhang of the second overhang structure has an end point further than under the first overhang structure and the third overhang structure.

13. The device of claim 9, wherein the first structure is disposed over a pixel defining layer (PDL) structure.

14. The device of claim 13, wherein the second overhang structure has different height from a substrate than the first overhang structure a different height than the first overhang of the plurality of overhang structures.

15. The device of claim 9, wherein the auxiliary electrode comprises a conductive material.

16. A device comprising a plurality of sub-pixels, each sub-pixel of the plurality of sub-pixels defined by adjacent pixel-defining layer (PDL) structures with a plurality of overhang structures disposed over a plurality of PDL structures, each sub-pixel of the plurality of sub-pixels having an anode, an auxiliary electrode, an organic light-emitting (OLE) material disposed on the anode, and a cathode disposed on the OLE material, wherein the device is made by a process comprising the steps of:
depositing the OLE material using evaporation deposition over a substrate, the OLE material disposed over and in contact with the anode;
depositing the cathode using evaporation deposition, the cathode disposed over the OLE material and extending under the overhang structures adjacent to each sub-pixel of the plurality of sub-pixels; and
depositing an encapsulation layer disposed over the cathode, the encapsulation layer extending under at least a portion of the overhang structures and along a sidewall of the overhang structures.

17. The device of claim 16 further comprising:
each overhang structure of the plurality of overhang structures comprising:
a first structure having a first portion opposing a second portion;
a second structure disposed over the first structure, wherein:
an overhang of the second structure extends laterally past an upper surface of the first structure to define the overhang; and
the auxiliary electrode is disposed partially under the second portion; and
wherein the cathode contacts the auxiliary electrode.

18. The device of claim 16, further comprising:
a first sub-pixel defined by a first overhang structure and a second overhang structure;
a second sub-pixel, the second sub-pixel is defined by the second overhang structure and a third overhang structure, each overhang structure of the plurality of overhang structures comprises:
a first structure; and
a second structure disposed over the first structure, wherein:
an overhang of the second structure extends laterally past an upper surface of the first structure to define the overhang; and
the second overhang structure has the auxiliary electrode disposed under the first structure; and
wherein each of the first sub-pixel and the second sub-pixel include:
an organic light emitting (OLE) material; and
the cathode disposed over the OLE material, the cathode contacts the auxiliary electrode of the second overhang structure.

19. The device of claim 18, wherein the cathode contacts the sidewall of the first structure of the second overhang structure and the cathode contacts the auxiliary electrode and wherein the cathode under the overhang of the second overhang structure has an end point further than under the first overhang structure and the third overhang structure.

20. The device of claim 16, wherein the auxiliary electrode comprises a conductive material.
